(19) United States
(12) Patent Application Publication
(10) Pub. No.: US 2025/0380502 A1
(43) Pub. Date: Dec. 11, 2025

(54) GATE-ALL-AROUND TRANSISTOR WITH SOURCE OR DRAIN REGIONS EXTENDING OVER SPACER STRUCTURES

(71) Applicant: Intel Corporation, Santa Clara, CA (US)

(72) Inventor: Xia Li, San Diego, CA (US)

(73) Assignee: Intel Corporation, Santa Clara, CA (US)

(21) Appl. No.: 18/736,946

(22) Filed: Jun. 7, 2024

(51) Int. Cl. H01L 27/092; H01L 29/06; H01L 29/08; H01L 29/423; H01L 29/66; H01L 29/775; H01L 29/786

(52) U.S. Cl. CPC H10D 84/85; H10D 30/014; H10D 30/031; H10D 30/43; H10D 30/6735; H10D 30/6757; H10D 62/121; H10D 62/151; H10D 64/017; H10D 64/018

(57) ABSTRACT

Techniques are provided herein to form an integrated circuit having different semiconductor devices with different features to cause opposite or otherwise different changes in the threshold voltage. For example, one or more first semiconductor devices include source or drain regions that extend laterally beneath a portion of the spacer structures to cause a decrease in the device threshold voltage, and one or more second semiconductor devices include thinned nanowires to cause an increase in the device threshold voltage. The one or more first FETs have source or drain regions that extend laterally inwards towards the nanoribbons between inner gate spacers, such that the interface between the source or drain regions and the nanoribbons is within a lateral width of the inner spacers. The one or more second FETs have nanoribbons with a smaller thickness within the gate trench compared to the nanoribbons of the one or more first FETs.

### BACKGROUND

As integrated circuits continue to scale downward in size, a number of challenges arise. For instance, reducing the size of memory and logic cells within the interconnect structure is becoming increasingly more difficult, as is reducing device spacing at the device layer. Each device may not have the same purpose within the integrated circuit, and thus fabrication procedures that benefit the operation of one device may not benefit (or even be detrimental) to the other. Accordingly, there remain a number of non-trivial challenges with respect to forming such high-density semiconductor devices.

### BRIEF DESCRIPTION OF THE DRAWINGS

FIG. 1A is a cross-sectional view of a semiconductor device in an integrated circuit that includes source or drain regions that extend laterally beneath the spacer structures, in accordance with an embodiment of the present disclosure.

FIG. 1B is a cross-sectional view of a semiconductor device in an integrated circuit that includes thinned nanoribbons, in accordance with an embodiment of the present disclosure.

FIGS. 2A and 2B are cross-sectional views that illustrate one stage in an example process for forming an integrated circuit having first semiconductor devices with source or drain regions that extend laterally beneath the spacer structures as shown in FIG. 1A and second semiconductor devices with thinned nanoribbons as shown in FIG. 1B, in accordance with an embodiment of the present disclosure.

FIGS. 3A and 3B are cross-sectional views that illustrate another stage in the example process for forming an integrated circuit having first semiconductor devices with source or drain regions that extend laterally beneath the spacer structures as shown in FIG. 1A and second semiconductor devices with thinned nanoribbons as shown in FIG. 1B, in accordance with an embodiment of the present disclosure.

FIGS. 4A and 4B are cross-sectional views that illustrate another stage in the example process for forming an integrated circuit having first semiconductor devices with source or drain regions that extend laterally beneath the spacer structures as shown in FIG. 1A and second semiconductor devices with thinned nanoribbons as shown in FIG. 1B, in accordance with an embodiment of the present disclosure.

FIGS. 5A and 5B are cross-sectional views that illustrate another stage in the example process for forming an integrated circuit having first semiconductor devices with source or drain regions that extend laterally beneath the spacer structures as shown in FIG. 1A and second semiconductor devices with thinned nanoribbons as shown in FIG. 1B, in accordance with an embodiment of the present disclosure.

FIGS. 6A and 6B are cross-sectional views that illustrate another stage in the example process for forming an integrated circuit having first semiconductor devices with source or drain regions that extend laterally beneath the spacer structures as shown in FIG. 1A and second semiconductor devices with thinned nanoribbons as shown in FIG. 1B, in accordance with an embodiment of the present disclosure.

FIGS. 7A and 7B are cross-sectional views that illustrate another stage in the example process for forming an integrated circuit having first semiconductor devices with source or drain regions that extend laterally beneath the spacer structures as shown in FIG. 1A and second semiconductor devices with thinned nanoribbons as shown in FIG. 1B, in accordance with an embodiment of the present disclosure.

FIGS. 8A and 8B are cross-sectional views that illustrate another stage in the example process for forming an integrated circuit having first semiconductor devices with source or drain regions that extend laterally beneath the spacer structures as shown in FIG. 1A and second semiconductor devices with thinned nanoribbons as shown in FIG. 1B, in accordance with an embodiment of the present disclosure.

FIGS. 9A and 9B are cross-sectional views that illustrate another stage in the example process for forming an integrated circuit having first semiconductor devices with source or drain regions that extend laterally beneath the spacer structures as shown in FIG. 1A and second semiconductor devices with thinned nanoribbons as shown in FIG. 1B, in accordance with an embodiment of the present disclosure.

FIGS. 10A and 10B are cross-sectional views that illustrate another stage in the example process for forming an integrated circuit having first semiconductor devices with source or drain regions that extend laterally beneath the spacer structures as shown in FIG. 1A and second semiconductor devices with thinned nanoribbons as shown in FIG. 1B, in accordance with an embodiment of the present disclosure.

FIGS. 11A and 11B are cross-sectional views that illustrate another stage in the example process for forming an integrated circuit having first semiconductor devices with source or drain regions that extend laterally beneath the spacer structures as shown in FIG. 1A and second semiconductor devices with thinned nanoribbons as shown in FIG. 1B, in accordance with an embodiment of the present disclosure.

FIGS. 12A and 12B are cross-sectional views that illustrate another stage in the example process for forming an integrated circuit having first semiconductor devices with source or drain regions that extend laterally beneath the spacer structures as shown in FIG. 1A and second semiconductor devices with thinned nanoribbons as shown in FIG. 1B, in accordance with an embodiment of the present disclosure.

FIGS. 13A and 13B are cross-sectional views that illustrate a stage in another example process for forming an integrated circuit having first semiconductor devices with source or drain regions that extend laterally beneath the spacer structures as shown in FIG. 1A and second semiconductor devices with thinned nanoribbons as shown in FIG. 1B, in accordance with an embodiment of the present disclosure.

FIG. 14 is a cross-sectional view that illustrates an example semiconductor device with source or drain regions that extend laterally beneath the spacer structures on only one side of the device, in accordance with an embodiment of the present disclosure.

FIG. 15 illustrates a cross-sectional view of a chip package containing one or more semiconductor dies, in accordance with some embodiments of the present disclosure.

FIG. 16 is a flowchart of a fabrication process for an integrated circuit that includes first semiconductor devices with source or drain regions that extend laterally beneath the spacer structures and second semiconductor devices with thinned nanoribbons, in accordance with an embodiment of the present disclosure.

FIG. 17 illustrates a computing system including one or more integrated circuits, as variously described herein, in accordance with an embodiment of the present disclosure.

Although the following Detailed Description will proceed with reference being made to illustrative embodiments, many alternatives, modifications, and variations thereof will be apparent in light of this disclosure. As will be further appreciated, the figures are not necessarily drawn to scale or intended to limit the present disclosure to the specific configurations shown. For instance, while some figures generally indicate perfectly straight lines, right angles, and smooth surfaces, an actual implementation of an integrated circuit structure may have less than perfect straight lines, right angles (e.g., some features may have tapered sidewalls and/or rounded corners), and some features may have surface topology or otherwise be non-smooth, given real world limitations of the processing equipment and techniques used.

### DETAILED DESCRIPTION

Techniques are provided herein to form an integrated circuit having different semiconductor devices with different features to cause opposite or otherwise different changes in threshold voltage. For example, one or more first semiconductor devices include source or drain regions that extend laterally beneath a portion of the spacer structures to cause a decrease in the device threshold voltage, and one or more second semiconductor devices include thinned nanowires to cause an increase in the device threshold voltage. The techniques can be used separately or in combination on the same die, and in any number of integrated circuit applications and are particularly useful with respect to logic and memory cells, such as those cells that use gate-all-around transistors (e.g., ribbonFETs and nanowire FETs) or forksheet transistors. In one such example, FETs (field effect transistors) each includes semiconductor material extending in a first direction between source and drain regions, and gate structures extending in a second direction around the semiconductor material of each FET. The semiconductor material of each FET may be, for instance, one to four nanowires (or nanoribbons or nanosheets, as the case may be). According to some embodiments, one or more first FETs have source or drain regions that extend laterally inwards towards the nanoribbons and between the inner gate spacers, such that the interface between the source or drain regions and the nanoribbons occurs along the lateral width of the inner spacers. The extended source or drain regions lower the channel resistance and cause a reduction in the threshold voltage of the one or more first FETs. According to some embodiments, one or more second FETs have nanoribbons with a smaller thickness within the gate trench compared to the nanoribbons of the one or more first FETs. The thinned nanoribbons raise the channel resistance and cause an increase in the threshold voltage of the one or more second FETs. Numerous variations and embodiments will be apparent in light of this disclosure.

### General Overview

As previously noted above, there remain a number of non-trivial challenges with respect to integrated circuit fabrication. In more detail, gate-all-around (GAA) devices may be used for different tasks within a given integrated circuit. For example, some devices may require high switching speeds (e.g., high frequency devices) at the cost of higher power, while other devices may be designed to operate with low power consumption. This device criteria can be difficult to achieve across a given circuit, as alterations to improve the performance of one type of device may have adverse effects for the other type of device. For example, the high frequency devices show improved performance with lower threshold voltage while the lower frequency, lower power devices show improved performance with higher threshold voltage to reduce leakage.

Thus, and in accordance with an embodiment of the present disclosure, techniques are provided herein to form semiconductor devices, on the same die, having diverse threshold voltages. In one example, one or more first GAA semiconductor devices are formed with decreased threshold voltage, and one or more second GAA semiconductor devices are formed with increased threshold voltage, within the same integrated circuit. According to an embodiment, the threshold voltage is decreased in the one or more first GAA devices by reducing the channel resistance along the length of the nanoribbons (or nanowires or nanosheets). The channel resistance is reduced by laterally extending the source or drain regions into the channel area between the inner spacer structures at the edges of the gate trench. In this way, the threshold voltage of the one or more first GAA devices may be decreased, for instance, by up to 30 mV while maintaining a constant nanoribbon thickness along its entire length (e.g., between about 6 nm and about 10 nm, such as between about 7 nm and about 8 nm).

According to an embodiment, the threshold voltage is increased in the one or more second GAA devices by reducing the thickness of the nanoribbons along their length (e.g., reducing the thickness of the nanoribbons within the gate trench between the spacer structures). The channel resistance is increased by reducing the cross-sectional area of the nanoribbons (e.g., thinning the exposed portions of the nanoribbons within the gate trench). In this way, the threshold voltage of the one or more second GAA devices may be increased, for instance, by up to 10-30 mV. According to some embodiments, the nanoribbons of the one or more second GAA devices may be thinned to a final thickness between about 3 nm and about 7 nm, such as between about 5 nm and about 6 nm. Other examples may be configured differently.

According to an embodiment, an integrated circuit includes: a first semiconductor device having a first semiconductor body extending in a first direction (e.g., left to right of page) from a first source or drain region and a first gate structure extending in a second direction (e.g., into and out of page) over the one or more first semiconductor nanoribbons; a second semiconductor device having a second semiconductor body extending in the first direction from a second source or drain region and a second gate structure extending in the second direction over the one or more second semiconductor nanoribbons; a first inner spacer adjacent to an end of the first semiconductor body such that the first inner spacer is between the first gate structure and the first source or drain region along the first direction; and a second inner spacer adjacent to an end of the second semiconductor body such that the second inner spacer is between the second gate structure and the second source or drain region along the first direction. Portions of the first source or drain region extend onto top and bottom surfaces of the first inner spacer. In some such cases, the first semiconductor body has a first thickness in a third direction (e.g., top to bottom of page), and the second semiconductor body has a second thickness in the third direction that is less than the first thickness by at least 2 nm. In some cases, the portions of the first source or drain region extend along the top and bottom surfaces of the first inner spacer in the first direction for a distance between about 1 nm and about 4 nm. In this manner, the interface between the first semiconductor body and the first source or drain region occurs along the lateral width (in the first direction) of the first inner spacer.

According to another embodiment, an integrated circuit includes a semiconductor device having one or more semiconductor nanoribbons extending in a first direction from a source or drain region and a gate structure extending in a second direction over the one or more semiconductor nanoribbons, and inner spacers adjacent to ends of the semiconductor nanoribbons. The second direction is substantially orthogonal to the first direction. The inner spacers are between the gate structure and the source or drain region along the first direction. Portions of the source or drain region are between adjacent inner spacers along a third direction substantially orthogonal to the first and second directions.

According to an embodiment, a method of forming an integrated circuit includes: forming a first fin and a second fin, each comprising layers of first semiconductor material alternating with layers of second semiconductor material, the first and second fins extending above a substrate and extending lengthwise along a first direction; forming a sacrificial gate extending over the first fin and second fin along a second direction and forming spacer structures on sidewalls of the sacrificial gate; removing portions of the first fin and second fin not protected by the sacrificial gate and sidewall structures; laterally recessing exposed ends of the layers of first semiconductor material of the first and second fins to form first lateral recesses; forming inner spacers within the first lateral recesses; masking the second fin using a mask material; laterally recessing exposed ends of the layers of second semiconductor material of the first fin to form second lateral recesses; remove the mask material around the second fin; forming a first source or drain region at exposed ends of the layers of second semiconductor material of the first fin, such that the first source or drain region forms within the second lateral recesses; and forming a second source or drain region at exposed ends of the layers of second semiconductor material of the second fin.

The techniques can be used with any type of planar or non-planar transistors, including nanowire and nanoribbon transistors (sometimes called gate-all-around transistors) or forksheet transistors, to name a few examples. The source and drain regions can be, for example, epitaxial regions that are deposited during an etch-and-replace source/drain forming process. The dopant-type in the source and drain regions will depend on the polarity of the corresponding transistor. The gate structure can be implemented with a gate-first process or a gate-last process (sometimes called a replacement metal gate, or RMG, process), or any other gate formation process. Any number of semiconductor materials can be used in forming the transistors, such as group IV materials (e.g., silicon, germanium, silicon germanium) or group III-V materials (e.g., gallium arsenide, indium gallium arsenide).

Use of the techniques and structures provided herein may be detectable using tools such as electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. For instance, in some example embodiments, such tools may indicate the extension of the source or drain regions along the lateral width of the internal spacer structures toward the channel region, for certain devices. In some example embodiments, one or more semiconductor devices may include thinned nanoribbons (e.g., at least 2 nm thinner) within the gate trench (e.g., contacting the gate structure) compared to other devices on the same chip.

It should be readily understood that the meaning of “above” and “over” in the present disclosure should be interpreted in the broadest manner such that “above” and “over” not only mean “directly on” something but also include the meaning of over something with an intermediate feature or a layer therebetween. Further, spatially relative terms, such as “beneath,” “below,” “lower,” “above,” “upper,” “top,” “bottom,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “layer” refers to a material portion including a region with a thickness. A monolayer is a layer that consists of a single layer of atoms of a given material. A layer can extend over the entirety of an underlying or overlying structure, or may have an extent less than the extent of an underlying or overlying structure. Further, a layer can be a region of a homogeneous or inhomogeneous continuous structure, with the layer having a thickness less than the thickness of the continuous structure. For example, a layer can be located between any pair of horizontal planes between, or at, a top surface and a bottom surface of the continuous structure. A layer can extend horizontally, vertically, and/or along a tapered surface. A layer can be conformal to a given surface (whether flat or curvilinear) with a relatively uniform thickness across the entire layer.

Materials that are “compositionally different” or “compositionally distinct” as used herein refers to two materials that have different chemical compositions. This compositional difference may be, for instance, by virtue of an element that is in one material but not the other (e.g., SiGe is compositionally different than silicon), or by way of one material having all the same elements as a second material but at least one of those elements is intentionally provided at a different concentration in one material relative to the other material (e.g., SiGe having 70 atomic percent germanium is compositionally different than from SiGe having 25 atomic percent germanium). In addition to such chemical composition diversity, the materials may also have distinct dopants (e.g., gallium and magnesium) or the same dopants but at differing concentrations. In still other embodiments, compositionally distinct materials may further refer to two materials that have different crystallographic orientations. For instance, (110) silicon is compositionally distinct or different from (100) silicon. Creating a stack of different orientations could be accomplished, for instance, with blanket wafer layer transfer. If two materials are elementally different, then one of the material has an element that is not in the other material.

### Architecture

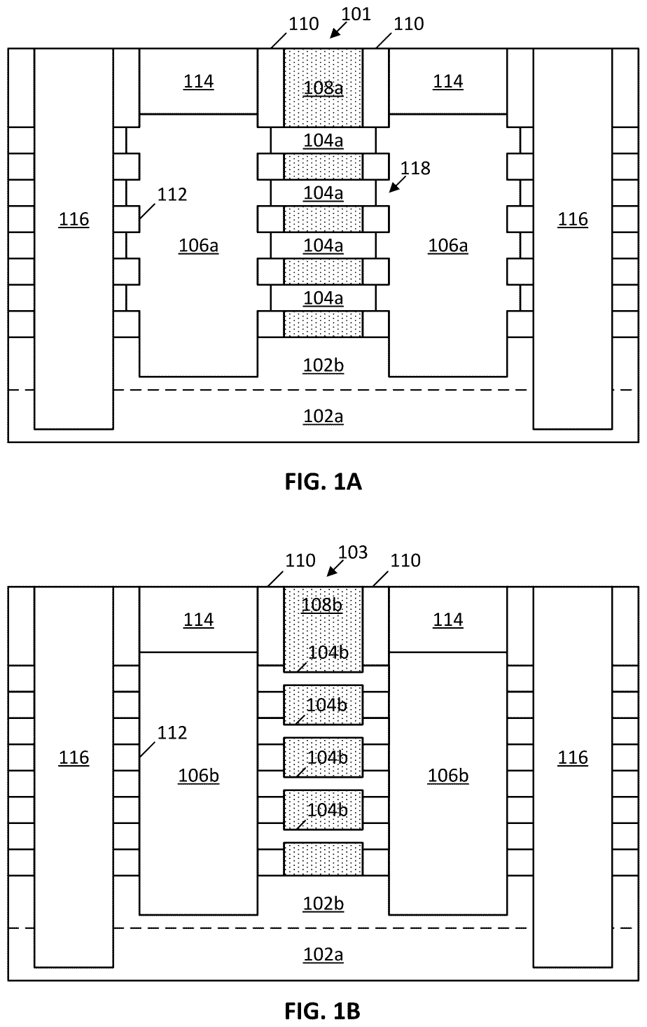

FIG. 1A is a cross-section view taken through a first semiconductor device 101 along a ‘fin’ direction that illustrates the semiconductor bodies extending between source or drain regions of first semiconductor device 101, in accordance with an embodiment of the present disclosure. FIG. 1B illustrates a cross-section view taken through a second semiconductor device 103 on the same die as first semiconductor device 101. Second semiconductor device 103 may be further along the same fin as first semiconductor device 101, or may be part of a different fin extending parallel to the fin of first semiconductor device 101. As used herein, the term ‘fin’ can refer to the original fin-shaped semiconductor structure from which nanoribbons, nanowires, or nanosheets are formed. Each of the semiconductor devices may be, for instance, non-planar metal oxide semiconductor (MOS) transistors, such gate-all-around (GAA) transistors, although other transistor topologies and types could also benefit from the techniques provided herein. The examples herein illustrate semiconductor devices with a GAA structure (e.g., having nanoribbons, nanowires, or nanosheets that extend between source and drain regions). Other examples may have a forksheet structure having a p-type device and an n-type device separated by a dielectric spine or structure.

The semiconductor material used in each of the semiconductor devices may be formed from or on a semiconductor substrate. According to some embodiments, the substrate is removed following the completion of all topside processing and is replaced with a base dielectric structure. The base dielectric structure may represent any number of dielectric layers and/or materials.

According to some embodiments, the substrate may include a bulk portion 102a and a doped well 102b. Bulk portion 102a may be a lightly doped semiconductor, such as a silicon substrate with p-type dopants (e.g., boron). Doped well 102b may be a top layer or portion of the substrate with a heavier dopant concentration (either n or p) depending on the type of transistor. In examples, where the semiconductor devices are n-channel devices, doped well 102b includes a high concentration of p-type dopants (e.g., boron). In examples, where the semiconductor devices are p-channel devices, doped well 102b includes a high concentration of n-type dopants (e.g., phosphorous or arsenic). Doped well 102b may have a thickness between 10 nm to 30 nm, although greater thicknesses are possible as well.

The one or more semiconductor regions of the devices may include fins of alternating layers of material (e.g., alternating layers of silicon and SiGe) that facilitates forming of nanowires and nanoribbons and nanosheets during a gate forming process where one type of the alternating layers is selectively etched away so as to liberate the other type of alternating layers within the channel region, so that a gate-all-around process or a forksheet gate process can then be carried out. The alternating layers can be blanket deposited and then etched into fins or deposited into fin-shaped trenches, in some examples.

First semiconductor device 101 includes one or more semiconductor regions (also called channel regions), such as one or more nanoribbons 104a extending between epitaxial first source or drain regions 106a in the first direction. Similarly, second semiconductor device 103 includes one or more semiconductor nanoribbons 104b extending between epitaxial second source or drain regions 106b in the first direction. First gate structure 108a extends over nanoribbons 104a of first semiconductor device 101 in a second direction (e.g., into and out of the page) to form the transistor gate of first semiconductor device 101 and second gate structure 108b extends over nanoribbons 104b of second semiconductor device 103 in the second direction to form the transistor gate of second semiconductor device 103.

Any of source or drain regions 106a/106b may act as either a source region or a drain region, depending on the application and dopant profile. Any semiconductor materials suitable for source and drain regions can be used (e.g., group IV and group III-V semiconductor materials) for any of the illustrated source or drains regions 106a/106b. In any such cases, the composition and doping of source or drain regions 106a and 106b may be the same or different, depending on the polarity of the transistors. In an example, the semiconductor devices may be n-channel devices having a high concentration of n-type dopants in the associated source or drain regions 106a/106b. In another example, the semiconductor devices may be p-channel devices having a high concentration of p-type dopants in the associated source or drain regions 106a/106b. Example p-type dopants include boron and example n-type dopants include phosphorous or arsenic. Any number of source and drain configurations and materials can be used. Note that source or drain regions 106a/106b may extend into a portion of doped well 102b, which includes the opposite dopant type from source or drain regions 106a/106b to reduce leakage.

The gate structures 108a/108b may each include a gate electrode that is made up of a conductive fill and one or more metal workfunction layers, according to some embodiments. The gate structures 108a/108b also include a gate dielectric that may represent any number of dielectric layers. The conductive fill may include any sufficiently conductive material such as a metal, metal alloy, or doped polysilicon. In some examples, the conductive fill includes tungsten (W), although other metals or conductive materials may be used, such as aluminum (Al), molybdenum (Mo), ruthenium (Ru), cobalt (Co), or doped polysilicon. In some embodiments, the semiconductor devices are n-channel devices having gate structures 108a/108b with one or more workfunction layers of tungsten. Other metal workfunction layers of n-channel devices can include tantalum nitride (TaN). In some embodiments, the semiconductor devices are p-channel devices having gate structures 108a/108b with one or more workfunction layers of molybdenum nitride (MoN). Other metal workfunction layers of p-channel devices can include tantalum nitride (TaN) and titanium nitride (TiN).

The gate dielectric of each gate structure 108a/108b may include any suitable gate dielectric material(s). In some embodiments, the gate dielectric includes a layer of native oxide material (e.g., silicon dioxide germanium dioxide, or SiGe oxide) on nanoribbons 104a/104b, and a layer of high-k dielectric material (e.g., hafnium oxide or aluminum oxide) on the native oxide. According to some embodiments, spacer structures 110 and inner spacers 112 are present along the sidewalls of gate structures 108a/108b. Spacer structures 110 and inner spacers 112 may be any suitable dielectric material, such as silicon nitride, and provide separation between a given gate structure 108a/108b and the adjacent source or drain region 106a/106b. Inner spacers 112 may separate adjacent nanoribbons 104a/104b from one another along a third direction (e.g., a vertical direction).

According to some embodiments, a dielectric fill 114 may be used within the source/drain trenches over both first source or drain regions 106a and second source or drain regions 106b. Dielectric fill 114 may be any suitable dielectric material, such as silicon dioxide or silicon oxynitride. In some examples, dielectric fill 114 extends along the source/drain trench in the second direction (into and out of the page) between adjacent source or drain regions along the source/drain trench. In some examples, one or more topside conductive contacts may be formed through dielectric fill 114 to contact top surfaces of any of source or drain regions 106a/106b.

According to some embodiments, one or more fin isolation structures 116 may be formed adjacent that cut across one or more fins to isolate devices on either side of the isolation structure. Fin isolation structures 116 may include one or more dielectric materials that extend in the second direction within a gate trench to cut through any number of fins present within the gate trench. In the illustrated example, fin isolation structures 116 extend along the second direction on either side of first semiconductor device 101 and second semiconductor device 103 to isolate such devices from any other devices formed along the first direction. Fin isolation structure 116 may include any suitable dielectric material, such as silicon nitride or any other high-k dielectric material. According to some embodiments, fin isolation structure 116 extends in the third direction along at least an entire height of the adjacent source or drain regions 106a/106b. A top surface of fin isolation structure 116 may be substantially coplanar with a top surface of spacer structures 110. In the example shown, fin isolation structure 116 extends through an entire thickness of doped well 102b, such that fin isolation structure 116 extends into bulk substrate 102a. Fin isolation structures 116 may not be needed in situations where adjacent devices along the first direction are intended to share a given source or drain region (or where dummy transistors are employed).

According to some embodiments, first source or drain regions 106a include protrusions 118 that laterally extend between inner spacers 112. Accordingly, these portions of first source or drain regions 106a extend onto top and bottom surfaces of inner spacers 112. The total length of nanoribbons 104a along the first direction is effectively shortened due to the encroachment of protrusions 118. According to some embodiments, protrusions 118 have a lateral width along the first direction between about 1 nm and about 4 nm.

According to some embodiments, nanoribbons 104b of second semiconductor device 103 are thinner compared to nanoribbons 104a of first semiconductor device 101. Nanoribbons 104b may be thinned within the gate trench (e.g., the portion that contacts gate structure 108b). As such, other portions of nanoribbons 104b between inner spacers 112 may have the original thickness and are not thinned. According to some embodiments, the thinned portion of nanoribbons 104b is at least 2 nm thinner compared to the thickness of nanoribbons 104a and/or compared to the thickness of the portions of nanoribbons 104b between the inner spacers along the third direction. The thinned portions of nanoribbons 104b may have a thickness between about 5 nm and about 6 nm.

### Fabrication Methodology

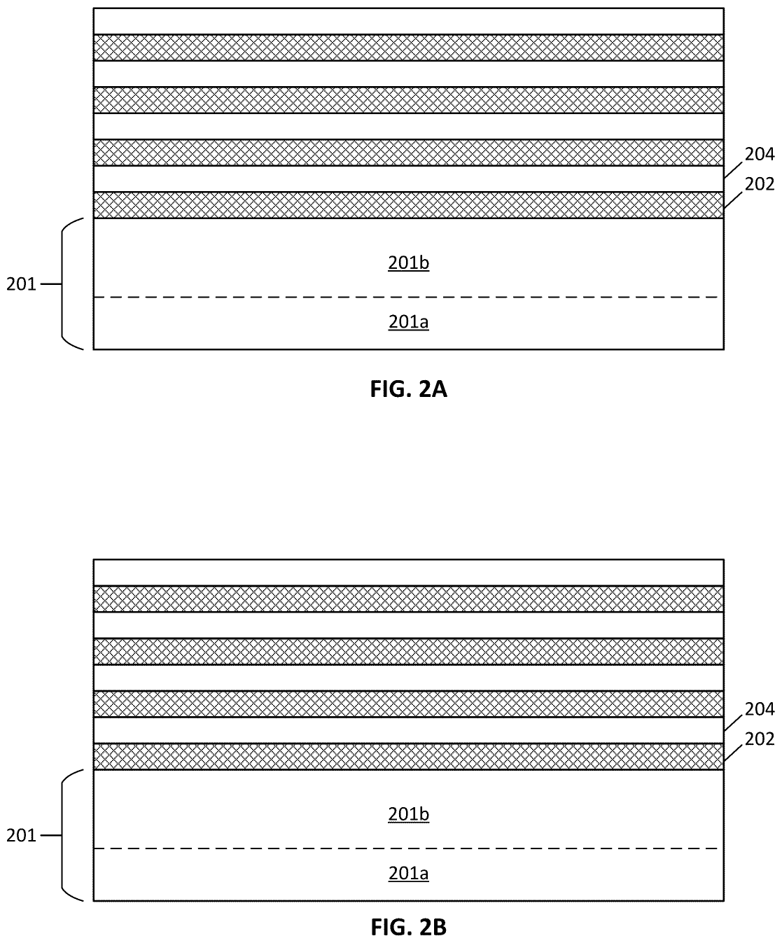

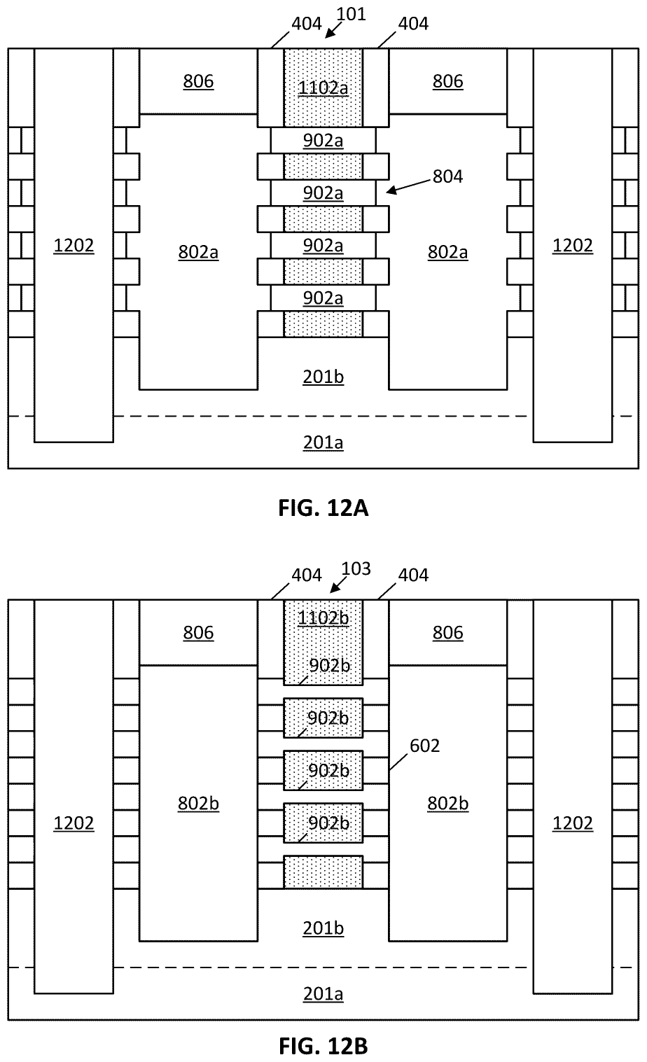

FIGS. 2A-12A and 2B-12B include cross-sectional views that collectively illustrate an example process for forming an integrated circuit that includes semiconductor devices with different features to yield different threshold voltages, in accordance with an embodiment of the present disclosure. FIGS. 2A-12A represent a similar cross-sectional view as that of FIG. 1A, while FIGS. 2B-12B represent a similar cross-sectional view as that of FIG. 1B parallel to the view in FIGS. 2A-12A. Each set of figures sharing the same letter shows an example structure that results from the process flow up to that point in time, so the depicted structure evolves as the process flow continues, culminating in the structure shown in FIGS. 12A and 12B, which is similar to the structure shown in FIGS. 1A and 1B. Such a structure may be part of an overall integrated circuit (e.g., such as a processor or memory chip) that includes, for example, digital logic cells and/or memory cells and analog mixed signal circuitry. Thus, the illustrated integrated circuit structure may be part of a larger integrated circuit that includes other integrated circuitry not depicted. Example materials and process parameters are given, but other materials and process parameters may be used as well, as will be appreciated in light of this disclosure.

FIGS. 2A and 2B each illustrates a cross-sectional view taken through a substrate 201 having a series of material layers formed over substrate 201, according to an embodiment of the present disclosure. Alternating material layers may be deposited over substrate 201 including sacrificial layers 202 alternating with semiconductor layers 204. The alternating layers are used to form GAA transistor structures. Any number of alternating sacrificial layers 202 and semiconductor layers 204 may be deposited over substrate 201. Substrate 201 may include a bulk portion 201a and a doped well 201b similar to bulk portion 102a and doped well 102b discussed above with reference to FIGS. 1A and 1B.

According to some embodiments, semiconductor layers 204 have a different material composition than sacrificial layers 202. In some embodiments, semiconductor layers 204 include a semiconductor material suitable for use as a nanoribbon such as silicon (Si), SiGe, germanium, or III-V materials like indium phosphide (InP) or gallium arsenide (GaAs). Sacrificial layers 202 include a material that can be selectively removed relative to semiconductor layers 204. In some examples, for instance, semiconductor layers 204 are silicon and sacrificial layers 202 are SiGe, or vice-versa. In some other examples where SiGe is used in each of semiconductor layers 204 and in sacrificial layers 202, the germanium concentration is different between semiconductor layers 204 and sacrificial layers 202, so as to allow for etch selectivity. For example, semiconductor layers 204 may include a higher germanium content compared to sacrificial layers 202.

While dimensions can vary from one example embodiment to the next, the thickness of each semiconductor layer 204 may be between about 5 nm and about 20 nm, such as between about 6 nm and about 10 nm. In some embodiments, the thickness of each semiconductor layer 204 is substantially the same (e.g., within 1 nm). The thickness of each of sacrificial layers 202 may be about the same as the thickness of each semiconductor layer 204 (e.g., about 6-10 nm). Each of semiconductor layers 204 and sacrificial layers 202 may be deposited using any material deposition technique, such as chemical vapor deposition (CVD), plasma-enhanced chemical vapor deposition (PECVD), physical vapor deposition (PVD), or atomic layer deposition (ALD), or epitaxial growth.

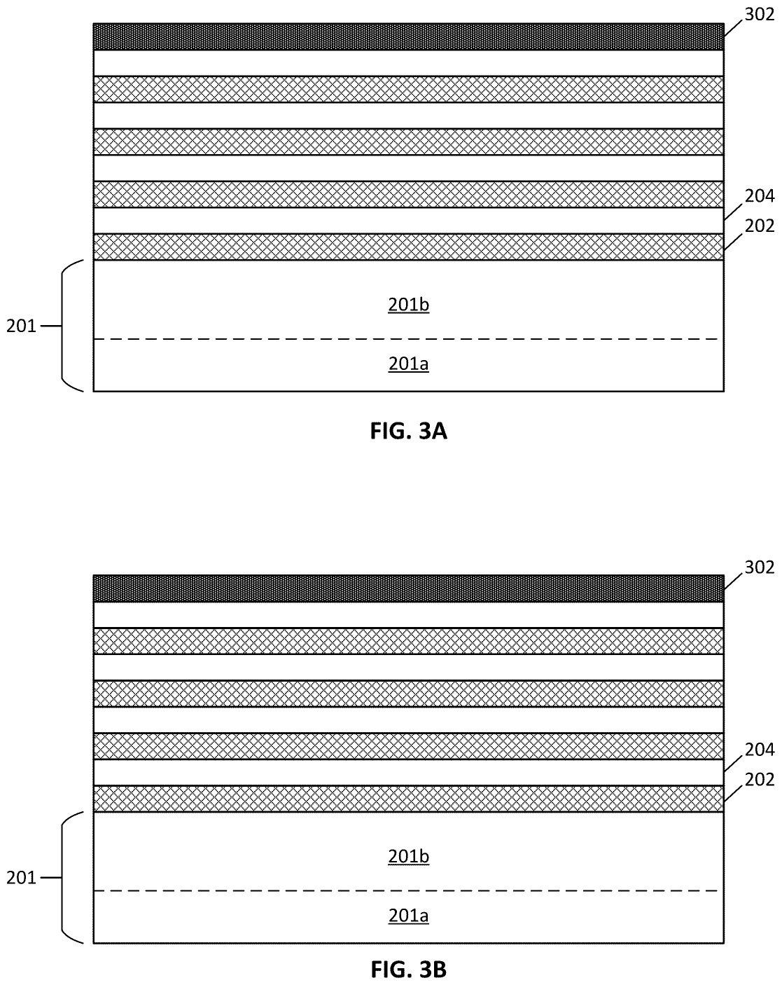

FIGS. 3A and 3B depict the cross-section views of the structure shown in FIGS. 2A and 2B, respectively, following the formation of a cap layer 302 and the subsequent formation of fins beneath cap layer 302, according to an embodiment. Cap layer 302 may be any suitable hard mask material such as a carbon hard mask (CHM) or silicon nitride. Cap layer 302 is patterned into rows to form corresponding rows of fins from the alternating layer stack of sacrificial layers 202 and semiconductor layers 204. Cap layer 302 extends along the top of each fin in a first direction.

According to some embodiments, an anisotropic etching process through the layer stack continues into at least a portion of substrate 201 (such as through at least the thickness of doped well 201b. Portions of substrate 201 beneath the fins are not etched and yield subfin regions. The etched portions of substrate 201 that are not under the fins may be filled with a dielectric fill that acts as shallow trench isolation (STI) between adjacent fins. The dielectric fill may be any suitable dielectric material such as silicon dioxide.

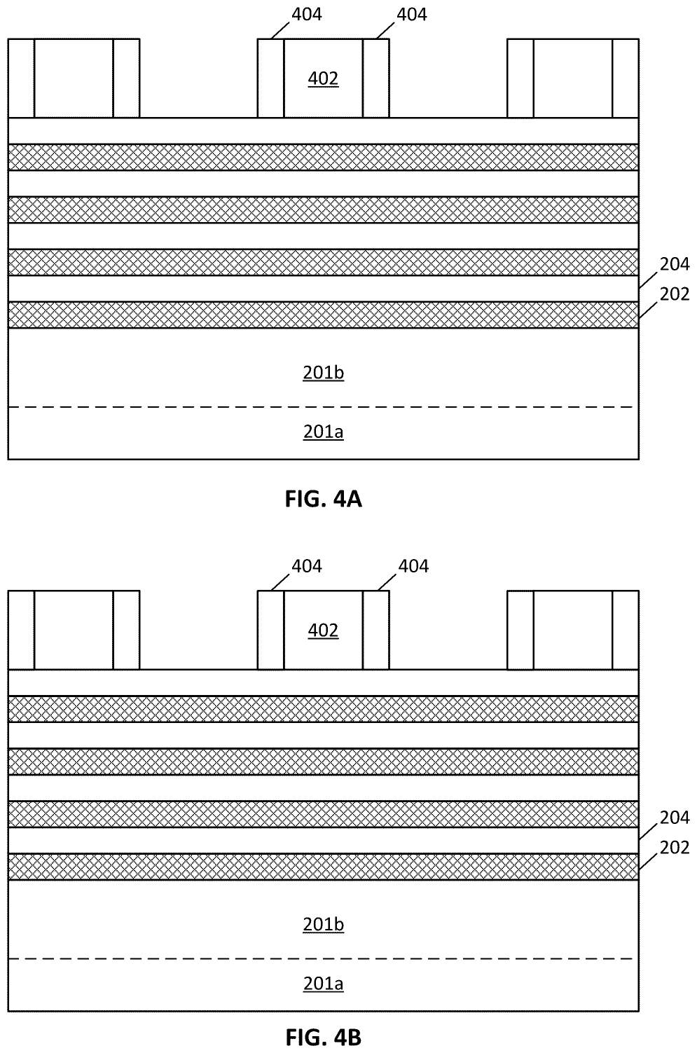

FIGS. 4A and 4B depict cross-section views of the structures shown in FIGS. 3A and 3B following the formation of sacrificial gates 402 and spacer structures 404, according to some embodiments. A gate masking layer may first be patterned in strips that extend orthogonally across each of the fins (e.g., in a second direction) in order to form corresponding sacrificial gates 402 in strips beneath the gate masking layers. Afterwards, the gate masking layers may be removed or may remain as a cap layer above each sacrificial gate 402. According to some embodiments, the sacrificial gate material is removed in all areas not protected by the gate masking layers. Sacrificial gate 402 may be any suitable material that can be selectively removed without damaging the semiconductor material of the fins. In some examples, sacrificial gate 402 includes polysilicon.

According to some embodiments, spacer structures 404 are formed along the sidewalls of sacrificial gates 402. Spacer structures 404 may be conformally deposited (e.g., CVD or ALD) and then etched back or otherwise removed (e.g., via anisotropic or directional etch) from horizontal surfaces, such that spacer structures 404 remain mostly only on sidewalls of any exposed structures. The width of spacer structures 404 (along the first direction) may vary from one example to the next, but in some cases is in the range of 3 nm to 20 nm. According to some embodiments, spacer structures 404 may be any suitable dielectric material, such as silicon nitride, silicon carbon nitride, or silicon oxycarbonitride.

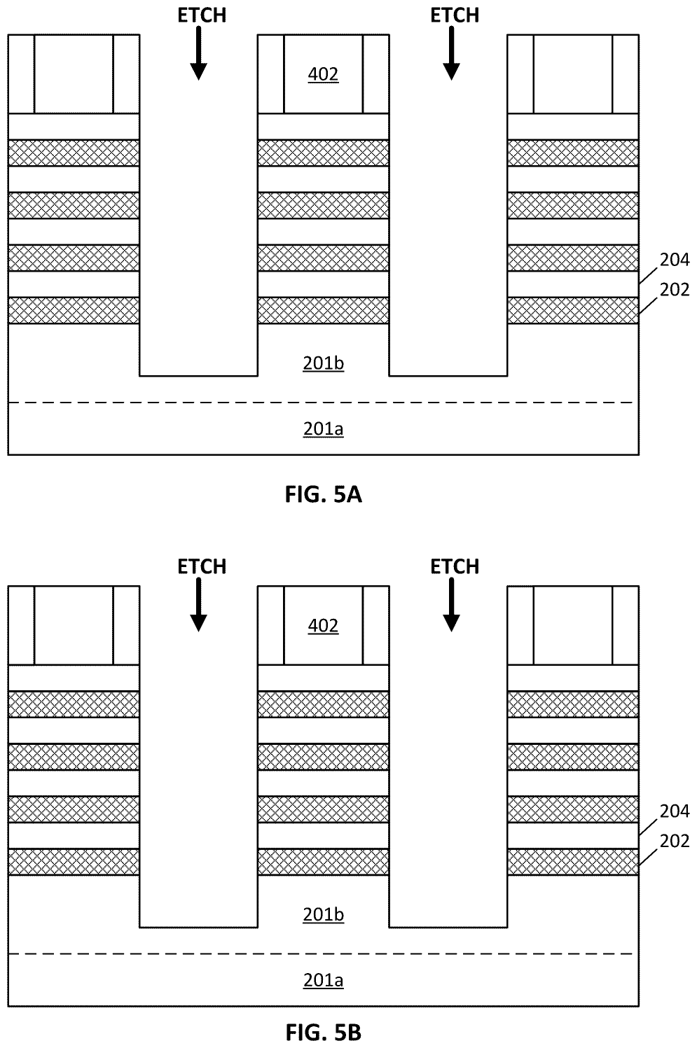

FIGS. 5A and 5B depict cross-section views of the structures shown in FIGS. 4A and 4B following the removal of exposed portions of the fins not protected by sacrificial gates 402 and spacer structures 404, according to some embodiments. The exposed fin portions may be removed using any anisotropic etching process, such as reactive ion etching (RIE) or other directional etch process. The removal of the exposed fin portions creates source or drain trenches that alternate with gate trenches (currently filled with sacrificial gates 402) along the first direction, according to some embodiments. In some embodiments, at least a portion of doped well 201b is also removed at the bottom of the recesses.

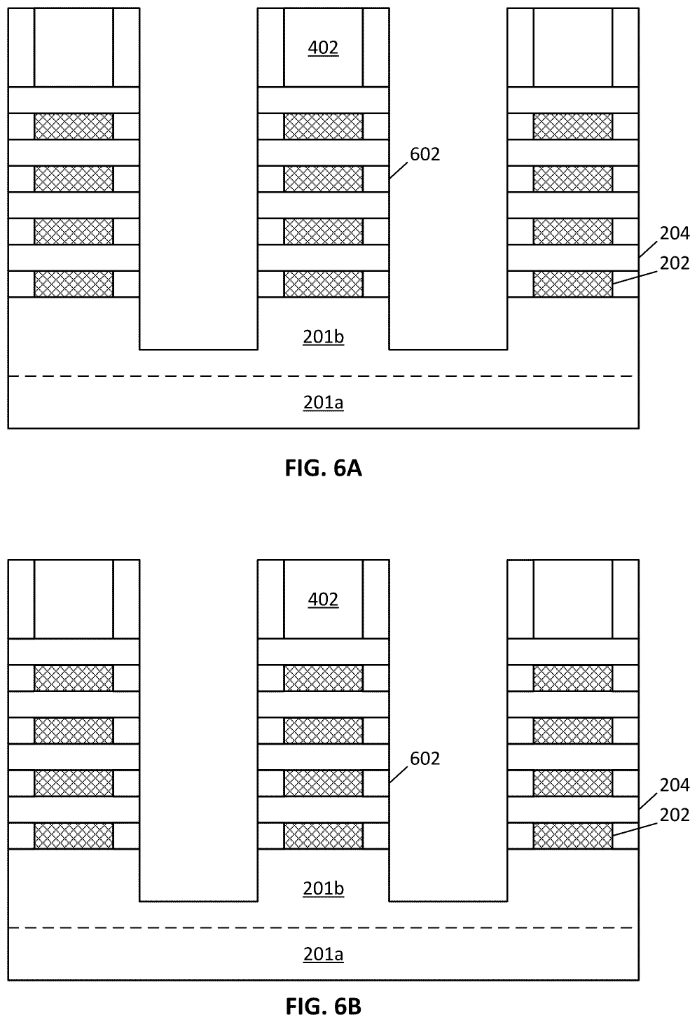

FIGS. 6A and 6B depict cross-section views of the structures shown in FIGS. 5A and 5B following the removal of portions of sacrificial layers 202 and formation of inner spacers 602 within the lateral recesses, according to an embodiment of the present disclosure. An isotropic etching process may be used to selectively recess the exposed ends of each sacrificial layer 202 (e.g., while etching comparatively little of semiconductor layers 204).

Inner spacers 602 may have a material composition that is similar to or the exact same as spacer structures 404. Accordingly, inner spacers 602 may be any suitable dielectric material that exhibits high etch selectively to semiconductor materials such as silicon and/or silicon germanium. Inner spacers 602 may be, for example, conformally deposited over the sides of the fin structure using a conformal deposition process like CVD or ALD and then etched back using an isotropic etching process to expose the ends of semiconductor layers 204. According to some embodiments, inner spacers 602 have a similar width (e.g., along the first direction) to spacer structures 404.

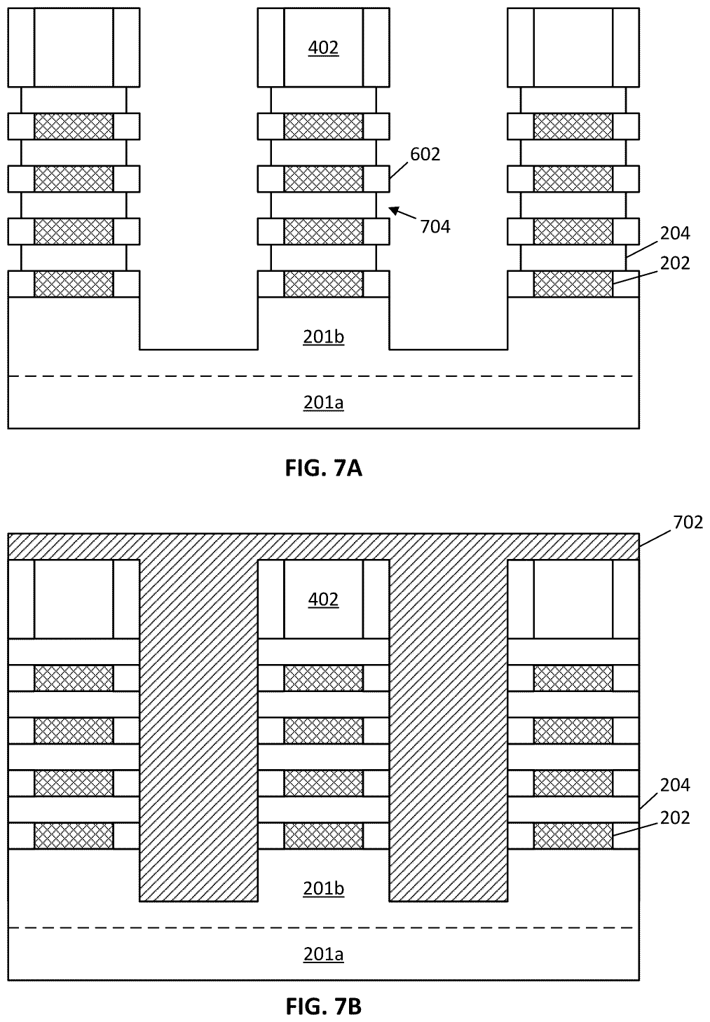

FIGS. 7A and 7B depict cross-section views of the structure shown in FIGS. 6A and 6B, respectively, following the lateral recessing of semiconductor layers 204 for the devices in FIG. 7A, while the devices in FIG. 7B are protected by a mask structure 702, according to some embodiments. Mask structure 702 may be any suitable hard mask material that can be lithographically patterned. In some examples, mask structure 702 includes carbon hard mask (CHM). Following the formation of mask structure 702 to protect any number of devices, those devices that remain exposed are subjected to an isotropic etching process to laterally etch semiconductor layers 204. According to some embodiments, lateral cavities 704 are formed between adjacent inner spacers 602 in the regions where the ends of semiconductor layers 204 have been etched. Lateral cavities 704 may have a dimension in the first direction between about 1 nm and about 4 nm.

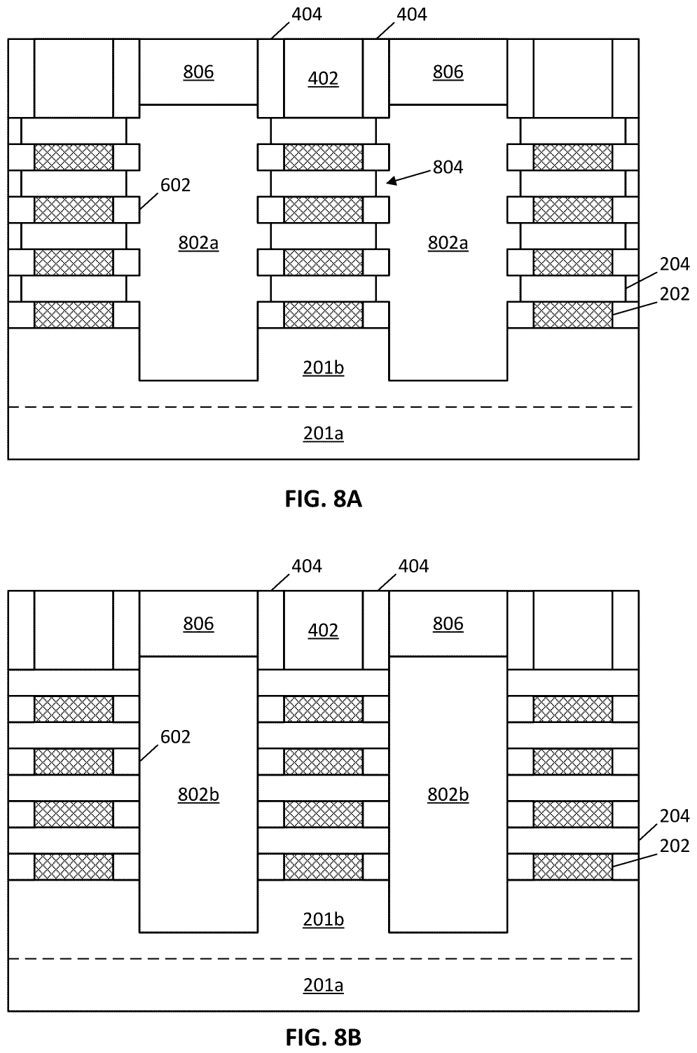

FIGS. 8A and 8B depict cross-section views of the structure shown in FIGS. 7A and 7B, respectively, following the formation of first source or drain regions 802a and second source or drain regions 802b within the source/drain trenches of the different devices, according to some embodiments. Source or drain regions 802a/802b may be formed in the areas that had been previously occupied by the exposed fins between spacer structures 404. According to some embodiments, source or drain regions 802a/802b are epitaxially grown from the exposed semiconductor material at the ends of semiconductor layers 204. In some embodiments, first source or drain regions 802a are grown from laterally recessed semiconductor layers 204. Accordingly, first source or drain regions 802a grow within lateral cavities 704 to form protrusions 804 that extend between inner spacers 602. Protrusions 804 contact portions of the upper and lower surfaces of inner spacers 602, according to some embodiments.

According to some embodiments, a dielectric fill 806 is provided over source or drain regions 802a/802b. In some examples, dielectric fill 806 occupies a remaining volume within the source/drain trenches around and over portions of source or drain regions 802a/802b. Dielectric fill 806 may be any suitable dielectric material, such as silicon dioxide. In some examples, dielectric fill 806 extends up to and planar with a top surface of spacer structures 404 (e.g., following a polishing procedure).

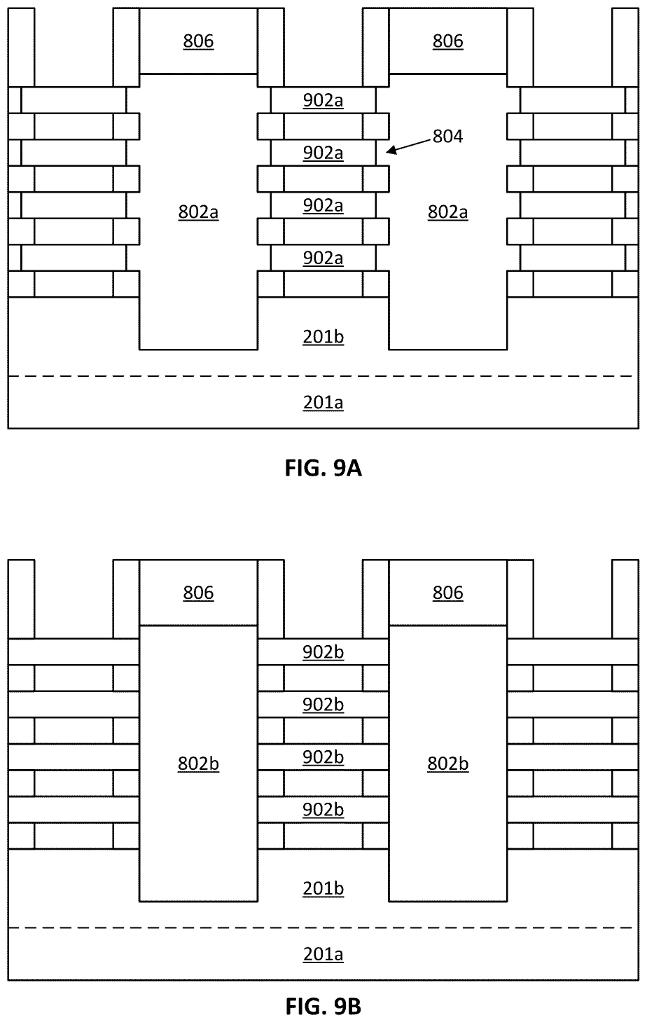

FIGS. 9A and 9B depict cross-section views of the structure shown in FIGS. 7A and 7B, respectively, following the removal of sacrificial gates 402 and sacrificial layers 202, according to some embodiments. In examples where gate masking layers are still present, they may be removed at this time. Once sacrificial gates 402 are removed, the fins extending between spacer structures 404 are exposed.

According to some embodiments, sacrificial layers 202 are selectively removed to leave behind first nanoribbons 902a that extend between corresponding first source or drain regions 802a and second nanoribbons 902b that extend between corresponding second source or drain regions 802b. Each vertical set of nanoribbons 902a/902b represents the semiconductor region (also called channel region) of a different semiconductor device. It should be understood that nanoribbons 902a/902b may also be nanowires or nanosheets. Sacrificial gates 402 and sacrificial layers 202 may be removed using the same isotropic etching process or different isotropic etching processes. Note that first nanoribbons 902a have a shorter length along the first direction compared to second nanoribbons 902b due to the presence of protrusions 804, according to some embodiments.

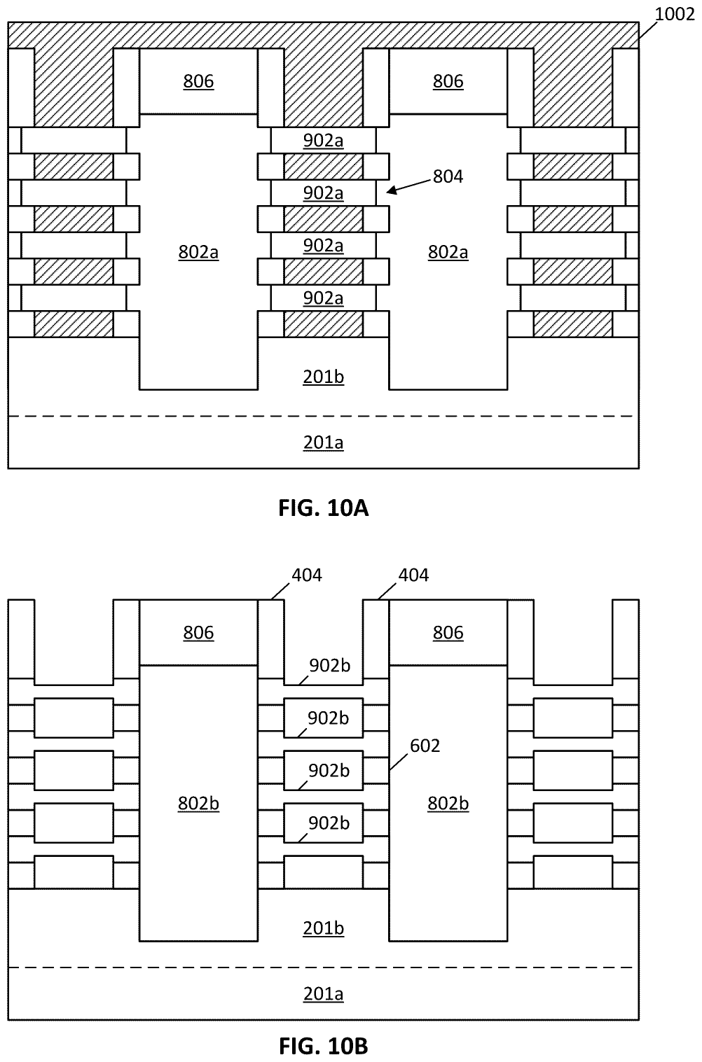

FIGS. 10A and 10B depict cross-section views of the structure shown in FIGS. 9A and 9B, respectively, following the thinning of portions of second nanoribbons 902b while protecting first nanoribbons 902a with a mask structure 1002, according to some embodiments. Mask structure 1002 may be any suitable hard mask material that can be lithographically patterned. In some examples, mask structure 1002 includes CHM. Following the formation of mask structure 1002 to protect any number of devices having protrusions 804, those devices that remain exposed are subjected a semiconductor thinning procedure to thin second nanoribbons 902b. According to some embodiments, an oxidation process is performed to oxidize the exposed semiconductor material of second nanoribbons 902b within the gate trench. In some examples, portions of second nanoribbons 902b may be oxidized (e.g., changed from silicon to silicon dioxide) at a depth of 1 nm to 3 nm beneath the surface of second nanoribbons 902b. An isotropic etching process may then be performed to remove the oxidized portion of second nanoribbons 902b, thus yielding the thinned regions of second nanoribbons 902b within the gate trench. Note that the portions of second nanoribbons 902b between inner spacers 602 along the third direction are not thinned as they are protected by inner spacers 602. According to some embodiments, the thinned region of second nanoribbons 902b may have a thickness that is at least 2 nm thinner compared to the thickness of first nanoribbons 902a and/or compared to the thickness of the portions of second nanoribbons 902b between inner spacers 602. The thinned region of second nanoribbons 902b may have a thickness between about 5 nm and about 6 nm.

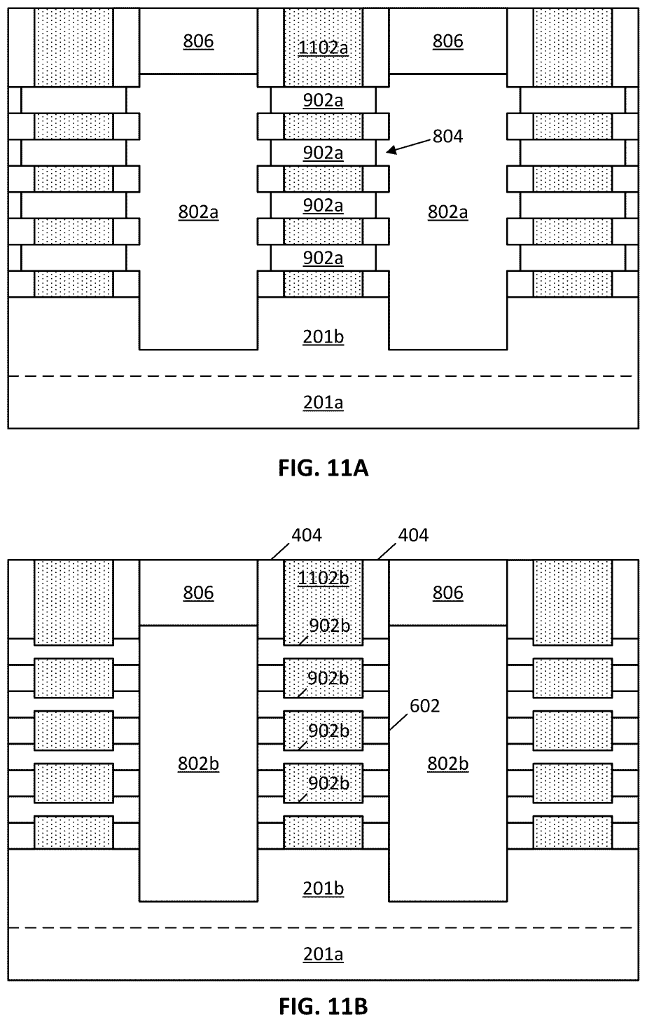

FIGS. 11A and 11B depict cross-section views of the structure shown in FIGS. 10A and 10B, respectively, following the formation of a first gate structure 1102a around first nanoribbons 902a and a second gate structure 1102b around second nanoribbons 902b, according to some embodiments. Each gate structure includes a gate dielectric and a gate electrode on the gate dielectric. The gate dielectric may be formed around nanoribbons 902a/902b and along any exposed surfaces within the gate trenches, such as along sidewalls of spacer structures 404. The gate dielectric may include any suitable dielectric material (such as silicon dioxide, and/or a high-k dielectric material). Examples of high-k dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, to provide some examples. According to some embodiments, the gate dielectric includes a layer of hafnium oxide with a thickness between about 1 nm and about 5 nm. In some embodiments, the gate dielectric may include one or more silicates (e.g., titanium silicate, tungsten silicate, niobium silicate, and silicates of other transition metals). In some cases, the gate dielectric includes a first layer on nanoribbons 902a/902b, and a second layer on the first layer. The first layer can be, for instance, an oxide of the semiconductor material of nanoribbons 902a/902b (e.g., silicon dioxide) and the second layer can be a high-k dielectric material (e.g., hafnium oxide or aluminum oxide). Any excess gate dielectric may be removed from the top surface of the structure, for instance, via a polishing process (e.g., chemical mechanical polishing, CMP).

The one or more conductive layers that make up the gate electrode may be deposited using electroplating, electroless plating, CVD, PECVD, ALD, or PVD, to name a few examples. In some embodiments, the gate electrode includes doped polysilicon, a metal, or a metal alloy. Example suitable metals or metal alloys include aluminum, tungsten, cobalt, molybdenum, ruthenium, titanium, tantalum, copper, and carbides and nitrides thereof. The gate electrode may include, for instance, a metal fill material along with one or more workfunction layers, resistance-reducing layers, and/or barrier layers. The workfunction layers can include, for example, p-type workfunction materials (e.g., titanium nitride) for PMOS gates, or n-type workfunction materials (e.g., titanium aluminum carbide) for NMOS gates.

FIGS. 12A and 12B depict cross-section views of the structure shown in FIGS. 11A and 11B, respectively, following the formation of fin isolation structures 1202 through one or more gate trenches, according to some embodiments. Fin isolation structures 1202 may include any number of dielectric materials and can extend across any number of fins along the second direction (into and out of the page). In the illustrated example, fin isolation structures 1202 isolate first semiconductor device 101 from any other adjacent devices along the first direction, and also isolate second semiconductor device 103 from any other adjacent devices along the first direction.

According to some embodiments, an RIE process is performed to etch openings through the gate trenches. The etch removes any exposed portion of the gate structure and nanoribbons within the gate trench. According to some embodiments, the openings extend through at least an entire height of the gate structures 1102a/1102b and into a portion of the substrate. In some examples, the openings extend through an entire height of doped well 201b into at least a portion of bulk substrate 201a. The openings may be filled with any number of dielectric materials to form fin isolation structures 1202. The dielectric material may be deposited using any suitable conformal deposition technique, such as ALD, CVD, or PECVD. The dielectric material may be any suitable dielectric, such as silicon nitride. According to some embodiments, the dielectric material is deposited and then polished back such that a top surface of fin isolation structures 1202 is substantially coplanar with a top surface of spacer structures 404.

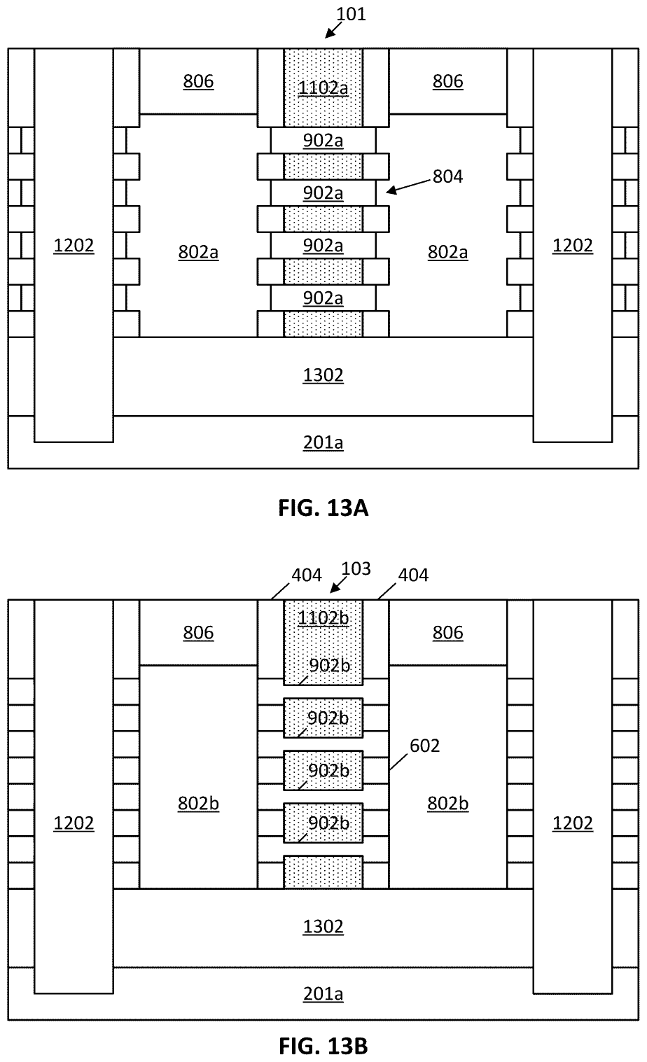

As noted above, some devices may be formed over a base dielectric layer, such as the case of silicon-on-insulator (SOI) substrates, rather than using doped well 201b. FIGS. 13A and 13B illustrate semiconductor devices 101 and 103 formed over base dielectric layer 1302 having bulk substrate 201a beneath base dielectric layer 1302, according to some embodiments. Base dielectric layer 1302 may be any suitable dielectric material, such as silicon dioxide. According to some embodiments, first source or drain regions 802a and second source or drain regions 802b do not extend into base dielectric layer 1302, as the base dielectric layer 1302 acts as an effective etch stop when forming the source/drain trenches. Bulk substrate 201a may remain to provide structural integrity, or may be removed and replaced with a backside interconnect region for routing signal or power to the devices.

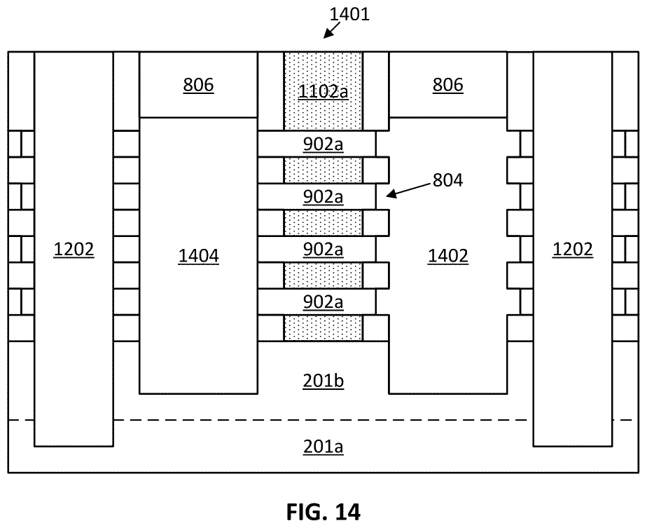

It should be noted that the lateral protrusions 804 of first source or drain regions 802a do not have to be present along both sides of the gate trench. In some examples, such protrusions 804 may be more beneficial when used with the source vs the drain. FIG. 14 illustrates an example device 1401 with protrusions 804 present along the right side of nanoribbons 902a, but not along the left side of nanoribbons 902a. When in use, first epitaxial region 1402 may act as a source while second epitaxial region 1404 may act as a drain. Protrusions 804 may be selectively formed along certain source/drain trenches by formed a suitable mask structure within other source/drain trenches to block the lateral etching of the semiconductor layers in those other source/drain trenches.

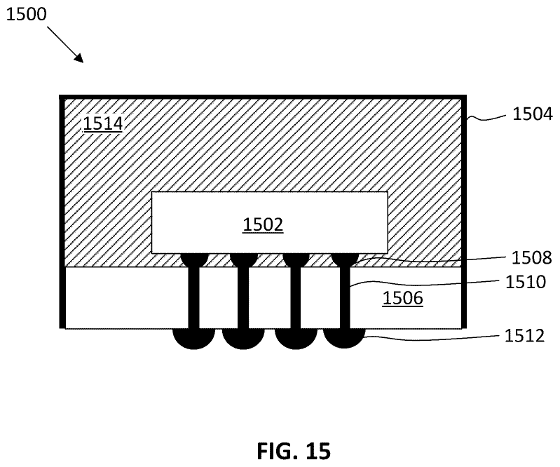

FIG. 15 illustrates an example embodiment of a chip package 1500, in accordance with an embodiment of the present disclosure. As can be seen, chip package 1500 includes one or more dies 1502. One or more dies 1502 may include at least one integrated circuit having semiconductor devices, such as any of the semiconductor devices disclosed herein. One or more dies 1502 may include any other circuitry used to interface with other devices formed on the dies, or other devices connected to chip package 1500, in some example configurations.

As can be further seen, chip package 1500 includes a housing 1504 that is bonded to a package substrate 1506. The housing 1504 may be any standard or proprietary housing, and may provide, for example, electromagnetic shielding and environmental protection for the components of chip package 1500. The one or more dies 1502 may be conductively coupled to a package substrate 1506 using connections 1508, which may be implemented with any number of standard or proprietary connection mechanisms, such as solder bumps, ball grid array (BGA), pins, or wire bonds, to name a few examples. Package substrate 1506 may be any standard or proprietary package substrate, but in some cases includes a dielectric material having conductive pathways (e.g., including conductive vias and lines) extending through the dielectric material between the faces of package substrate 1506, or between different locations on each face. In some embodiments, package substrate 1506 may have a thickness less than 1 millimeter (e.g., between 0.1 millimeters and 0.5 millimeters), although any number of package geometries can be used. Additional conductive contacts 1512 may be disposed at an opposite face of package substrate 1506 for conductively contacting, for instance, a printed circuit board (PCB). One or more vias 1510 extend through a thickness of package substrate 1506 to provide conductive pathways between one or more of connections 1508 to one or more of contacts 1512. Vias 1510 are illustrated as single straight columns through package substrate 1506 for ease of illustration, although other configurations can be used (e.g., damascene, dual damascene, through-silicon via, or an interconnect structure that meanders through the thickness of substrate 1506 to contact one or more intermediate locations therein). In still other embodiments, vias 1510 are fabricated by multiple smaller stacked vias, or are staggered at different locations across package substrate 1506. In the illustrated embodiment, contacts 1512 are solder balls (e.g., for bump-based connections or a ball grid array arrangement), but any suitable package bonding mechanism may be used (e.g., pins in a pin grid array arrangement or lands in a land grid array arrangement). In some embodiments, a solder resist is disposed between contacts 1512, to inhibit shorting.

In some embodiments, a mold material 1514 may be disposed around the one or more dies 1502 included within housing 1504 (e.g., between dies 1502 and package substrate 1506 as an underfill material, as well as between dies 1502 and housing 1504 as an overfill material). Although the dimensions and qualities of the mold material 1514 can vary from one embodiment to the next, in some embodiments, a thickness of mold material 1514 is less than 1 millimeter. Example materials that may be used for mold material 1514 include epoxy mold materials, as suitable. In some cases, the mold material 1514 is thermally conductive, in addition to being electrically insulating.

### Methodology

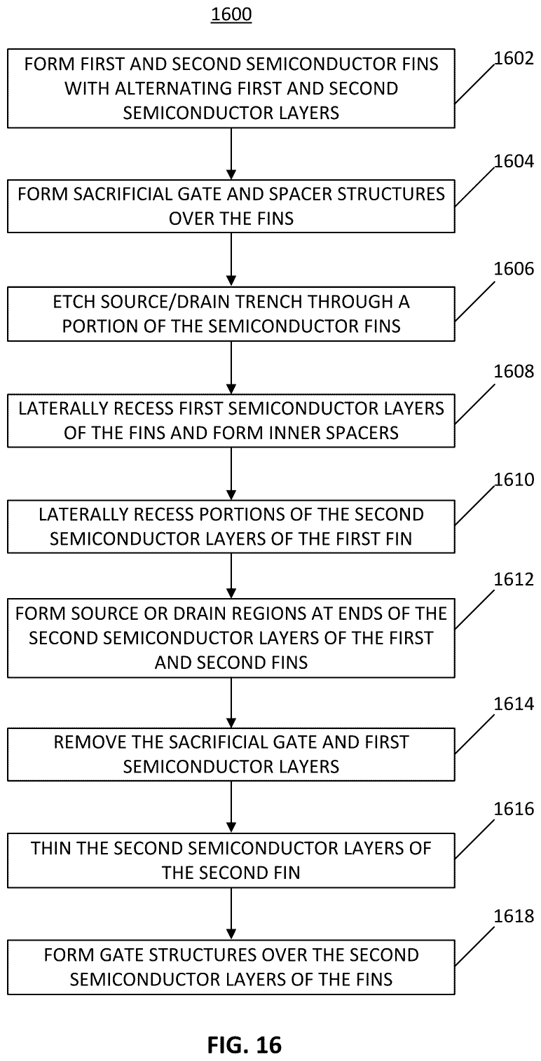

FIG. 16 is a flow chart of a method 1600 for forming at least a portion of an integrated circuit, according to an embodiment. Various operations of method 1600 may be illustrated in FIGS. 2A-12A and 2B-12B. However, the correlation of the various operations of method 1600 to the specific components illustrated in the aforementioned figures is not intended to imply any structural and/or use limitations. Rather, the aforementioned figures provide one example embodiment of method 1600. Other operations may be performed before, during, or after any of the operations of method 1600. For example, method 1600 does not explicitly describe various standard processes that are usually performed to form transistor structures. Some of the operations of method 1600 may be performed in a different order than the illustrated order.

Method 1600 begins with operation 1602 where first and second semiconductor fins are formed, according to some embodiments. The fins may be part of a plurality of similar fins formed across a substrate. The fins can be formed of material deposited onto an underlying substrate. In some embodiments, the fins include alternating layers of material (e.g., alternating first and second layers of silicon and SiGe) that facilitates forming of nanowires and nanoribbons during a gate forming process where one type of the alternating layers are selectively etched away so as to liberate the other type of alternating layers within the channel region, so that a gate-all-around (GAA) process can then be carried out. Again, the alternating first and second layers can be blanket deposited and then etched into fins, or deposited into fin-shaped trenches, according to some examples. The fins may also include a cap structure over each fin that is used to define the locations of the fins during, for example, an RIE process. The cap structure may be a dielectric material, such as silicon nitride.

Method 1600 continues with operation 1604 where sacrificial gates are formed over the first and second fins. The sacrificial gates may be part of a plurality of sacrificial gates patterned using gate masking layers in strips that run orthogonally over various fins and parallel to one another (e.g., forming a cross-hatch pattern). The gate masking layers may be any suitable hard mask material, such as CHM or silicon nitride. The sacrificial gate itself may be formed from any suitable material that can be selectively removed at a later time without damaging the semiconductor material of the fin. In one example, the sacrificial gate includes polysilicon.

According to some embodiments, spacer structures are also formed on sidewalls of the sacrificial gates. The spacer structures may be deposited and then etched back such that the spacer structures remain mostly only on sidewalls of any exposed structures. In some cases, spacer structures may also be formed along sidewalls of the exposed fin running orthogonally between the strips of sacrificial gates. According to some embodiments, the spacer structures may be any suitable dielectric material, such as silicon nitride or silicon oxynitride.

Method 1600 continues with operation 1606 where exposed portions of the fins are removed to form source/drain trenches. Any exposed portions of the fins not covered by the sacrificial gates or spacer structures may be removed using any anisotropic etching process, such as reactive ion etching (RIE). In some examples, portions of the subfin may also be removed during this process.

Method 1600 continues with operation 1608 where the first semiconductor layers of the first and second fins are laterally recessed to form first recessed cavities. According to some embodiments, an isotropic etching process may be used to etch the exposed ends of the first semiconductor layers while etching little to none of the second semiconductor layers. The first recessed cavities may have a lateral depth that is around the same width as the spacer structures (e.g., 5 nm-10 nm).

According to some embodiments, the first recessed cavities may be filled with a dielectric material to form inner spacers. The inner spacers may have a material composition that is similar to or the exact same as the spacer structures. Accordingly, the inner spacers may be any suitable dielectric material that exhibits high etch selectively to semiconductor materials such as silicon and/or silicon germanium, such as silicon nitride or silicon oxynitride. The inner spacers may be, for example, conformally deposited over the sides of the first and second fins using a conformal deposition process like CVD or ALD and then etched back using an isotropic etching process to expose the ends of the second semiconductor layers, thus leaving the inner spacers within the first cavities.

Method 1600 continues with operation 1610 where the exposed ends of the second semiconductor layers of the first fin are recessed to form second cavities. According to some embodiments, a mask structure (e.g., CHM) is patterned over the second fin to protect it from the etching process. An isotropic etching process may be used to laterally etch the second semiconductor layers of the first fin. According to some embodiments, the second cavities are formed between adjacent inner spacers in the regions where the ends of the second semiconductor layers have been etched. The second cavities may have a dimension in the first direction (e.g., along the length of the fin) between about 1 nm and about 4 nm.

Method 1600 continues with operation 1612 where source or drain regions are formed at opposite ends of the fin on the second semiconductor layers within the source/drain trenches. The source or drain regions may be formed in the areas that had been previously occupied by the exposed fin between the spacer structures. According to some embodiments, the source or drain regions are epitaxially grown from the second semiconductor layers. In some example embodiments, the source or drain regions are NMOS source or drain regions (e.g., epitaxial silicon with n-type dopants) or PMOS source or drain regions (e.g., epitaxial SiGe with p-type dopants). A dielectric fill may be formed between and over the source or drain regions along a given source/drain trench. The dielectric fill may be any suitable dielectric material, such as silicon dioxide. In some examples, the dielectric fill extends over the source or drain regions up to and planar with a top surface of the spacer structures. The dielectric fill also acts as an electrical insulator between adjacent source or drain regions, although some adjacent source or drain regions may have merged together during their growth or may include a gate cut structure separating them.

According to some embodiments, the source or drain regions formed at the ends of the first fin include protrusions into the second cavities. The protrusions contact portions of the upper and lower surfaces of the adjacent inner spacers and also contact the second semiconductor layers, according to some embodiments.

Method 1600 continues with operation 1614 where the sacrificial gate is removed. According to some embodiments, the sacrificial gate may be removed along with any sacrificial layers (e.g., the first semiconductor layers) within the exposed fins between the spacer structures. The sacrificial gate and/or sacrificial layers may be removed using any suitable isotropic etching process. The removal of the first and second fins' sacrificial layers leaves behind semiconductor nanoribbons (or nanowires or nanosheets) extending along the first direction between the source or drain regions.

Method 1600 continues with operation 1616 where the nanoribbons of the second fin are thinned compared to the nanoribbons of the first fin. According to an embodiment, a suitable mask structure (e.g., CHM) may be patterned to protect the nanoribbons of the first fin. The semiconductor nanoribbons of the second fin are thinned using any suitable semiconductor removal process. In some examples, an isotropic etch is performed to thin the exposed semiconductor material of the nanoribbons. In some other examples, an oxidation process is performed to oxidize the exposed nanoribbons of the second fin. An isotropic etching process may then be performed to remove the oxidized portion of the nanoribbons, thus yielding thinned regions of the nanoribbons of the second fin within the gate trench. Note that portions of the thinned nanoribbons between the inner spacers are not thinned as they are protected from the etch and/or oxidation process by the inner spacers. According to some embodiments, the thinned region of the nanoribbons in the second fin may have a thickness that is at least 2 nm thinner compared to the thickness of the nanoribbons from the first fin. The thinned region of the nanoribbons in the second fin may have a thickness between about 5 nm and about 6 nm.

Method 1600 continues with operation 1618 where gate structures are formed over the semiconductor nanoribbons of the first and second fins. The gate structures may be formed in the space previously occupied by the sacrificial gates and the sacrificial layers of the first and second fins. The gate structures may include both a gate dielectric and a gate electrode. The gate dielectric is first formed over the exposed semiconductor nanoribbons followed by forming the gate electrode within the remainder of the trench between the spacer structures, according to some embodiments. The gate dielectric may include any number of dielectric layers deposited using a CVD process, such as ALD. The gate electrode can include any conductive material, such as a metal, metal alloy, or polysilicon. The gate electrode may be deposited using electroplating, electroless plating, CVD, ALD, PECVD, or PVD, to name a few examples.

### Example System

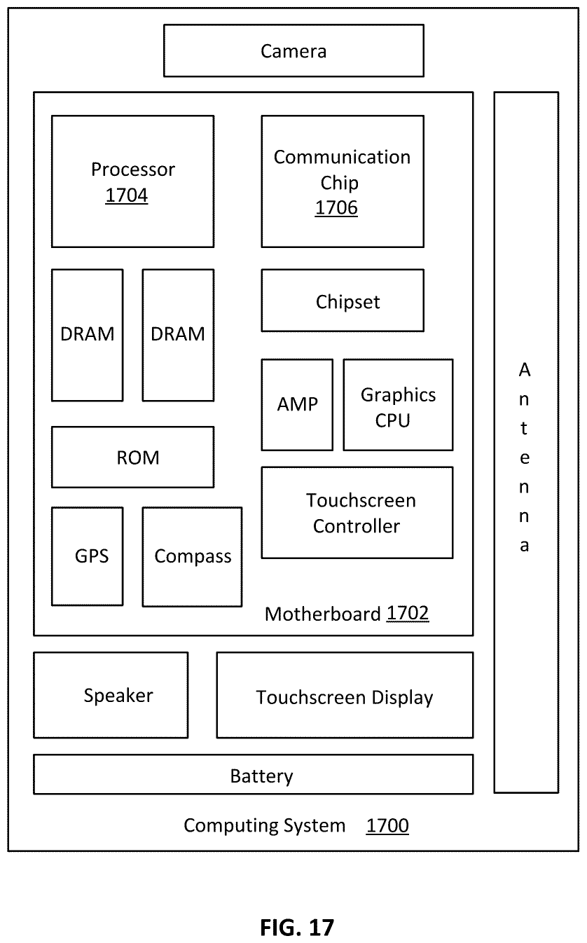

FIG. 17 is an example computing system implemented with one or more of the integrated circuit structures as disclosed herein, in accordance with some embodiments of the present disclosure. As can be seen, the computing system 1700 houses a motherboard 1702. The motherboard 1702 may include a number of components, including, but not limited to, a processor 1704 and at least one communication chip 1706, each of which can be physically and electrically coupled to the motherboard 1702, or otherwise integrated therein. As will be appreciated, the motherboard 1702 may be, for example, any printed circuit board (PCB), whether a main board, a daughterboard mounted on a main board, or the only board of system 1700, etc.

Depending on its applications, computing system 1700 may include one or more other components that may or may not be physically and electrically coupled to the motherboard 1702. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 1700 may include one or more integrated circuit structures or devices configured in accordance with an example embodiment (e.g., a module including an integrated circuit device on a substrate, the substrate having first semiconductor devices with source or drain regions that extend laterally beneath the spacer structures and second semiconductor devices with thinned nanoribbons, as variously provided herein). In some embodiments, multiple functions can be integrated into one or more chips (e.g., for instance, note that the communication chip 1706 can be part of or otherwise integrated into the processor 1704).

The communication chip 1706 enables wireless communications for the transfer of data to and from the computing system 1700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1706 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 1700 may include a plurality of communication chips 1706. For instance, a first communication chip 1706 may be dedicated to shorter range wireless communications such as Wi-Fi and Bluetooth and a second communication chip 1706 may be dedicated to longer range wireless communications such as GPS, EDGE, GPRS, CDMA, WiMAX, LTE, Ev-DO, and others.

The processor 1704 of the computing system 1700 includes an integrated circuit die packaged within the processor 1704. In some embodiments, the integrated circuit die of the processor includes onboard circuitry that is implemented with one or more semiconductor devices as variously described herein. The term “processor” may refer to any device or portion of a device that processes, for instance, electronic data from registers and/or memory to transform that electronic data into other electronic data that may be stored in registers and/or memory.

The communication chip 1706 also may include an integrated circuit die packaged within the communication chip 1706. In accordance with some such example embodiments, the integrated circuit die of the communication chip includes one or more semiconductor devices as variously described herein. As will be appreciated in light of this disclosure, note that multi-standard wireless capability may be integrated directly into the processor 1704 (e.g., where functionality of any chips 1706 is integrated into processor 1704, rather than having separate communication chips). Further note that processor 1704 may be a chip set having such wireless capability. In short, any number of processor 1704 and/or communication chips 1706 can be used. Likewise, any one chip or chip set can have multiple functions integrated therein.

In various implementations, the computing system 1700 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device that processes data or employs one or more integrated circuit structures or devices formed using the disclosed techniques, as variously described herein.

It will be appreciated that in some embodiments, the various components of the computing system 1700 may be combined or integrated in a system-on-a-chip (SoC) architecture. In some embodiments, the components may be hardware components, firmware components, software components or any suitable combination of hardware, firmware or software.

### Further Example Embodiments

The following examples pertain to further embodiments, from which numerous permutations and configurations will be apparent.

Example 1 is an integrated circuit that includes a first semiconductor device having a first semiconductor body extending in a first direction from a first source or drain region and a first gate structure extending in a second direction over the first semiconductor body, a second semiconductor device having a second semiconductor body extending in the first direction from a second source or drain region and a second gate structure extending in the second direction over the second semiconductor body, a first inner spacer adjacent to an end of the first semiconductor body, and a second inner spacer adjacent to an end of the second semiconductor body. The first inner spacer is between the first gate structure and the first source or drain region along the first direction, and the second inner spacer is between the second gate structure and the second source or drain region along the first direction. Portions of the first source or drain region extend onto top and bottom surfaces of the first inner spacer.

Example 2 includes the integrated circuit of Example 1, wherein the first semiconductor body has a first thickness in a third direction, and the second semiconductor body has a second thickness in the third direction that is less than the first thickness by at least 2 nm.

Example 3 includes the integrated circuit of Example 2, wherein the first thickness is between about 6 nm and about 10 nm.

Example 4 includes the integrated circuit of Example 2 or 3, wherein the second semiconductor body has a first section with the first thickness and a second section with the second thickness.

Example 5 includes the integrated circuit of Example 4, wherein the second gate structure contacts the second section of the second semiconductor body.

Example 6 includes the integrated circuit of Example 4 or 5, wherein the first section of the second semiconductor body is between the second section and the second source or drain region along the first direction.

Example 7 includes the integrated circuit of any one of Examples 4-6, wherein the first section of the second semiconductor body is on a top or bottom surface of the second inner spacer.

Example 8 includes the integrated circuit of any one of Examples 1-7, wherein the portions of the first source or drain region extend along the top and bottom surfaces of the first inner spacer in the first direction for a distance between about 1 nm and about 4 nm.

Example 9 includes the integrated circuit of any one of Examples 1-8, further comprising spacer structures on sidewalls of at least a top portion of the first gate structure.

Example 10 includes the integrated circuit of any one of Examples 1-9, wherein the first semiconductor body is one of multiple first nanoribbons, nanowires, or nanosheets that extend in the first direction from the first source or drain region, and the second semiconductor body is one of multiple second nanoribbons, nanowires, or nanosheets that extend in the first direction from the second source or drain region.

Example 11 includes the integrated circuit of Example 10, wherein a topmost one of the first nanoribbons, nanowires, or nanosheets extends beneath at least a portion of the spacer structures along the first direction.

Example 12 includes the integrated circuit of Example 10 or 11, wherein the first nanoribbons, nanowires, or nanosheets and the second nanoribbons, nanowires, or nanosheets comprise germanium, silicon, or a combination thereof.

Example 13 is a printed circuit board comprising the integrated circuit of any one of Examples 1-12.

Example 14 is an electronic device that includes a chip package having one or more dies. At least one of the one or more dies includes one or more first semiconductor nanoribbons extending in a first direction from a first source or drain region, a first gate structure extending in a second direction over the one or more first semiconductor nanoribbons, one or more second semiconductor nanoribbons extending in the first direction from a second source or drain region, a second gate structure extending in the second direction over the one or more second semiconductor nanoribbons, first inner spacers adjacent to ends of the first semiconductor nanoribbons, and second inner spacers adjacent to ends of the second semiconductor nanoribbons. The first inner spacers are between the first gate structure and the first source or drain region along the first direction, and the second inner spacers are between the second gate structure and the second source or drain region along the first direction. Portions of the first source or drain region extend onto top and bottom surfaces of the first inner spacers. The one or more first semiconductor nanoribbons have a first thickness in a third direction, and the one or more second semiconductor nanoribbons have a second thickness in the third direction that is less than the first thickness by at least 2 nm.

Example 15 includes the electronic device of Example 14, wherein the first thickness is between about 6 nm and about 10 nm.

Example 16 includes the electronic device of Example 14 or 15, wherein the one or more second semiconductor nanoribbons each have a first section with the first thickness and a second section with the second thickness.

Example 17 includes the electronic device of Example 16, wherein the second gate structure contacts the second section of each of the one or more second semiconductor nanoribbons.

Example 18 includes the electronic device of Example 16 or 17, wherein the first section of each of the one or more second semiconductor nanoribbons is between the second section and the second source or drain region along the first direction.

Example 19 includes the electronic device of Example 18, wherein the first section of each of the one or more second semiconductor nanoribbons is on a top or bottom surface of an adjacent second inner spacer.

Example 20 includes the electronic device of any one of Examples 14-19, wherein the portions of the first source or drain region have a greatest length along the first direction between about 1 nm and about 4 nm.

Example 21 includes the electronic device of any one of Examples 14-20, wherein the at least one of the one or more dies further comprises spacer structures on sidewalls of at least a top portion of the first gate structure.

Example 22 includes the electronic device of Example 21, wherein a topmost nanoribbon of the one or more first semiconductor nanoribbons extends beneath at least a portion of the spacer structures along the first direction.

Example 23 includes the electronic device of any one of Examples 14-22, wherein the one or more first semiconductor nanoribbons and one or more second semiconductor nanoribbons comprise germanium, silicon, or a combination thereof.

Example 24 includes the electronic device of any one of Examples 14-23, further comprising a printed circuit board, wherein the chip package is coupled to the printed circuit board.

Example 25 is a method of forming an integrated circuit. The method includes forming a first fin and a second fin, each comprising layers of first semiconductor material alternating with layers of second semiconductor material, the first and second fins extending above a substrate and extending lengthwise along a first direction; forming a sacrificial gate extending over the first fin and second fin along a second direction and forming spacer structures on sidewalls of the sacrificial gate; removing portions of the first fin and second fin not protected by the sacrificial gate and sidewall structures; laterally recessing exposed ends of the layers of first semiconductor material of the first and second fins to form first lateral recesses; forming inner spacers within the first lateral recesses; masking the second fin using a mask material; laterally recessing exposed ends of the layers of second semiconductor material of the first fin to form second lateral recesses; remove the mask material around the second fin; forming a first source or drain region at exposed ends of the layers of second semiconductor material of the first fin, such that the first source or drain region forms within the second lateral recesses; and forming a second source or drain region at exposed ends of the layers of second semiconductor material of the second fin.

Example 26 includes the method of Example 25, wherein the layers of first semiconductor material has a semiconductor material that is different than the layers of second semiconductor material.

Example 27 includes the method of Example 25 or 26, wherein the layers of first semiconductor material comprise silicon and germanium and the layers of second semiconductor material comprise silicon.

Example 28 includes the method of any one of Examples 25-27, further comprising removing the sacrificial gate; removing exposed portions of the layers of first semiconductor material between the spacer structures; masking the layers of second semiconductor material of the first fin; and thinning the layers of second semiconductor material of the second fin.

Example 29 includes the method of Example 28, wherein the thinning comprises thinning the layers of second semiconductor material of the second fin by at least 2 nm.

Example 30 includes the method of any one of Examples 25-29, wherein the second lateral recesses have a greatest length along the first direction between about 1 nm and about 3 nm.

Example 31 is an integrated circuit that includes a semiconductor device having one or more semiconductor nanoribbons extending in a first direction from a source or drain region and a gate structure extending in a second direction over the one or more semiconductor nanoribbons, and inner spacers adjacent to ends of the semiconductor nanoribbons such that the inner spacers are between the gate structure and the source or drain region along the first direction. The second direction is substantially orthogonal to the first direction. Portions of the source or drain region are between adjacent inner spacers along a third direction substantially orthogonal to the first and second directions.

Example 32 includes the integrated circuit of Example 31, wherein the portions of the source or drain region have a greatest length along the first direction between about 1 nm and about 4 nm.

Example 33 includes the integrated circuit of Example 31 or 32, further comprising spacer structures on sidewalls of at least a top portion of the gate structure.

Example 34 includes the integrated circuit of Example 33, wherein a topmost nanoribbon of the one or more semiconductor nanoribbons extends beneath at least a portion of the spacer structures along the first direction.

Example 35 includes the integrated circuit of any one of Examples 31-34, wherein the one or more semiconductor nanoribbons comprise germanium, silicon, or a combination thereof.

Example 36 includes the integrated circuit of any one of Examples 31-35, wherein the gate structure comprises a gate dielectric on the one or more semiconductor nanoribbons and a gate electrode on the gate dielectric.

Example 37 includes the integrated circuit of Example 36, wherein the gate dielectric comprises a high-k dielectric material.

Example 38 includes the integrated circuit of any one of Examples 31-37, wherein portions of the one or more semiconductor nanoribbons extend beneath the inner spacers to contact the portions of the source or drain region.

Example 39 is a printed circuit board comprising the integrated circuit of any one of Examples 31-38.

The foregoing description of the embodiments of the disclosure has been presented for the purposes of illustration and description. It is not intended to be exhaustive or to limit the disclosure to the precise forms disclosed. Many modifications and variations are possible in light of this disclosure. It is intended that the scope of the disclosure be limited not by this detailed description, but rather by the claims appended hereto.

What is claimed is:

1. An integrated circuit comprising:
a first semiconductor device having a first semiconductor body extending in a first direction from a first source or drain region, and a first gate structure extending in a second direction over the first semiconductor body;
a second semiconductor device having a second semiconductor body extending in the first direction from a second source or drain region, and a second gate structure extending in the second direction over the second semiconductor body;
a first inner spacer adjacent to an end of the first semiconductor body, such that the first inner spacer is between the first gate structure and the first source or drain region along the first direction; and
a second inner spacer adjacent to an end of the second semiconductor body, such that the second inner spacer is between the second gate structure and the second source or drain region along the first direction;
wherein portions of the first source or drain region extend onto top and bottom surfaces of the first inner spacer.

2. The integrated circuit of claim 1, wherein the first semiconductor body has a first thickness in a third direction, and the second semiconductor body has a second thickness in the third direction that is less than the first thickness by at least 2 nm.

3. The integrated circuit of claim 2, wherein the second semiconductor body has a first section with the first thickness and a second section with the second thickness.

4. The integrated circuit of claim 3, wherein the first section of the second semiconductor body is between the second section and the second source or drain region along the first direction.

5. The integrated circuit of claim 3, wherein the first section of the second semiconductor body is on a top or bottom surface of the second inner spacer.

6. The integrated circuit of claim 1, wherein the portions of the first source or drain region extend along the top and bottom surfaces of the first inner spacer in the first direction for a distance between about 1 nm and about 4 nm.

7. The integrated circuit of claim 1, wherein the first semiconductor body is one of multiple first nanoribbons, nanowires, or nanosheets that extend in the first direction from the first source or drain region, and the second semiconductor body is one of multiple second nanoribbons, nanowires, or nanosheets that extend in the first direction from the second source or drain region.

8. A printed circuit board comprising the integrated circuit of claim 1.

9. An electronic device, comprising:
a chip package comprising one or more dies, at least one of the one or more dies comprising
one or more first semiconductor nanoribbons extending in a first direction from a first source or drain region;
a first gate structure extending in a second direction over the one or more first semiconductor nanoribbons;
one or more second semiconductor nanoribbons extending in the first direction from a second source or drain region;
a second gate structure extending in the second direction over the one or more second semiconductor nanoribbons;
first inner spacers adjacent to ends of the first semiconductor nanoribbons, such that the first inner spacers are between the first gate structure and the first source or drain region along the first direction; and
second inner spacers adjacent to ends of the second semiconductor nanoribbons, such that the second inner spacers are between the second gate structure and the second source or drain region along the first direction;
wherein portions of the first source or drain region extend onto top surfaces and bottom surfaces of the first inner spacers; and
wherein the one or more first semiconductor nanoribbons have a first thickness in a third direction, and the one or more second semiconductor nanoribbons have a second thickness in the third direction that is less than the first thickness by at least 2 nm.

10. The electronic device of claim 9, wherein the first thickness is between about 6 nm and about 10 nm.

11. The electronic device of claim 9, wherein the one or more second semiconductor nanoribbons each have a first section with the first thickness and a second section with the second thickness.

12. The electronic device of claim 11, wherein the first section of each of the one or more second semiconductor nanoribbons is between the second section and the second source or drain region along the first direction.

13. The electronic device of claim 11, wherein the first section of each of the one or more second semiconductor nanoribbons is on a top or bottom surface of an adjacent second inner spacer.

14. The electronic device of claim 9, wherein the portions of the first source or drain region have a greatest length along the first direction between about 1 nm and about 4 nm.

15. An integrated circuit comprising:
a semiconductor device having one or more semiconductor nanoribbons extending in a first direction from a source or drain region, and a gate structure extending in a second direction over the one or more semiconductor nanoribbons, the second direction being substantially orthogonal to the first direction; and
inner spacers adjacent to ends of the semiconductor nanoribbons, such that the inner spacers are between the gate structure and the source or drain region along the first direction,
wherein portions of the source or drain region are between adjacent inner spacers along a third direction substantially orthogonal to the first and second directions.

16. The integrated circuit of claim 15, wherein the portions of the source or drain region have a greatest length along the first direction between about 1 nm and about 4 nm.

17. The integrated circuit of claim 15, further comprising spacer structures on sidewalls of at least a top portion of the gate structure.

18. The integrated circuit of claim 17, wherein a topmost nanoribbon of the one or more semiconductor nanoribbons extends beneath at least a portion of the spacer structures along the first direction.

19. The integrated circuit of claim 15, wherein the gate structure comprises a gate dielectric on the one or more semiconductor nanoribbons and a gate electrode on the gate dielectric.

20. The integrated circuit of claim 15, wherein portions of the one or more semiconductor nanoribbons extend beneath the inner spacers to contact the portions of the source or drain region.
